(19) United States
(12) Patent Application Publication
(10) Pub. No.: US 2003/0017632 A1
(43) Pub. Date: Jan. 23, 2003

(54) Structure and manufacturing process of printhead chip for an ink-jet printer

(75) Inventors: Fu-San Lin, Hsin-Chu (TW); Chin-Yi Chou, Hsin-Chu (TW); Ying-Lun Chang, Hsin-Chu (TW)

Correspondence Address: Dougherty & Troxell, ONE SKYLINE PLACE, SUITE 1404, 5205 LEESBURG PIKE, FALLS CHURCH, VA, 22041, US

(73) Assignee: Microjet Technology Co., Ltd.

(21) Appl. No.: 09/906,773

(22) Filed: Jul. 18, 2001

(51) Int. Cl. H01L 21/00

(52) U.S. Cl. 438/21

(57) ABSTRACT

The present invention relates generally to a structure and a manufacturing process of printhead chip for an ink jet printer, wherein the poor step coverage of the passivation layer (Si₃N₄), which generated at the step region of the resistive layer/conductive layer interface during the formation of thin films of the chip, is improved, and the undesirable weariness of the chip as a result of the thermal, mechanical, and chemical stresses is reduced. The structure of the present invention is obtained by using the same polycrystalline materials having the resistive properties as the resistive layer and conductive layer in order to eliminate the step coverage of the passivation layer and simultaneously planarizating the passivation layer.

### BACKGROUND OF THE INVENTION

1. Fields of the Invention

The present invention relates generally to a structure and a manufacturing process of printhead chip for an ink jet printer, and more especially to an improved structure and manufacturing process of printhead chip, wherein both resistive layer and conductive layer are made from the same materials in order to eliminate the step phenomenon.

2. Description of Related Art

In the manufacturing process of the conventional printhead chip for an ink jet printer, as shown in FIG. 1, a silicon dioxide thin film is first formed over a silicon substrate of the wafer as a thermal barrier layer, and then a resistive layer (TaAl) as a bottom layer and a conductive layer (Al) as a top layer are in turn deposited on the silicon dioxide layer by a sputtering process. Thereafter, the conductive layer and resistive layer are defined in sequence by photolithography and etching technique, and then a passivation layer (Si₃N₄/SiC) is deposited over the conductive layer/resistive layer using a sputtering equipment by a chemical vapor deposition (CVD) process. In such a manner of manufacturing, when the top conductive layer is defined by photolithography and etching technique, bevels are generated at the interface of the top conductive layer and bottom resistive layer which leads to the passivation layer to form a step phenomenon at the conductive layer/resistive layer interface as indicated by circles in FIG. 2. During the subsequent formation of the passivation layer, such a step phenomenon may cause the passivation layer to be subjected to accumulated stresses, and lead to the poor step coverage or unstable structure and the like.

The conventional manufacturing process of the printhead chip also has above disadvantages. For example, U.S. Pat. No. 4,809,428 discloses a process of fabricating thin film ink jet printheads. It is shown that there is still a step phenomenon at the conductive layer/resistive layer interface. Now referring to plan view of FIG. 3 and cross sectional view of FIG. 4, it is shown that there is still a step phenomenon at the conductive layer/resistive layer interface 34 during the formation of thin films for printhead chip. When the printhead is operating, the resistive layer, which is contacted with the heater elements, may be subjected to the environments of high currents, high temperature, mechanical impacts and chemical erosions. In such a circumstance, the passivation layer thereof may readily cause cracks or holes and thus lead to break. As a result, the ink may penetrate through the defects of the passivation layer into the conductive layer and resistive layer of the printhead chip, and therefore cause the damage of elements.

Furthermore, in U.S. Pat. Nos. 4,513,298 and 5,122,812, it is disclosed a structure of a thermal inkjet printhead wherein the phosphorous (P) is doped on the polycrystalline silicon layer by diffusion to form a resistive layer. However, the techniques of both patents are characterized by forming conductive layer and passivation layer over polycrystalline silicon layer, there is still a step phenomenon.

### DISCLOSURE OF THE INVENTION

The step phenomenon above described generally exists in the current manufacturing process of printhead chips for an ink jet printer and it is still necessary to develop a new process of fabrication to overcome this problem. The object of the invention is to provide a structure and manufacturing process of printhead chip for an ink jet printer, wherein the printhead chip is obtained by using the same materials as the resistive layer and conductive layer of the chip. In such a manner, the bevels may not be generated at the conductive layer/resistive layer interface when the conductive layer is defined and thus the step phenomenon of the passivation layer can be eliminated.

It is obvious from the purpose described above that the present invention is characterized by forming a polycrystalline silicon layer over the underlying thermal barrier layer using a CVD or other known methods per se, followed by defining the dimension of the desired resistive layer by depositing the photoresist; consequently the conductive layer is formed by doping the unmasked resistive region by ion implantation or diffusion method to increase the conductivity. Therefore the conductive layer and the resistive layer are formed simultaneously and located on the same layer. According to the process of the present invention, there is no step phenomenon at the interface between the conductive layer and the resistive layer.

Accordingly, the manufacturing process of the present invention includes the steps of: 1) forming a thermal barrier layer over the substrate; 2) forming a polycrystalline silicon layer with resistance over the thermal barrier layer; 3) defining the polycrystalline silicon layer to the desired dimension by photolithography and etching technique; 4) masking a resistive region which is predetermined to form a heater plate on the polycrystalline silicon layer by depositing photoresist and doping the unmasked region of polycrystalline silicon layer in order to form the first conductive layer, since the first conductive layer and the resistive layer are made from the same polycrystalline silicon material, both of them are planarly adjoined each other thereby to form a conductive/resistive layer; 5) forming a passivation layer over the first conductive layer and the resistive layer; 6) defining the via hole on the passivation layer by using the photolithography and etching technique; 7) forming the adhesion layer (Ta) and the second conductive layer (Au) by sputtering or other known methods per se; 8) defining the desired dimension by photolithography and etching technique to complete all the procedures.

In the following, the manufacturing process of the printhead chip of the present invention is described more detailedly, wherein the substrate may be a silicon substrate and the thermal barrier layer is formed over the silicon substrate by oxidation technique. The preferred embodiment of the thermal barrier layer may be a silicon dioxide layer.

A polycrystalline silicon layer with resistance is formed over a thermal barrier layer using a CVD or other known methods per se. The polycrystalline silicon layer can be used as a conductive material through the doping process to increase the charged carriers and reduce the resistivity. The-polycrystalline silicon layer is defined as the desired dimensions by photolithography and etching technique and a resistive region of it, which is predetermined to form a heater plate, is masked by depositing photoresist, whereas the unmasked region of polycrystalline silicon layer is doped in order to form the conductive layer. Since the conductive layer and the resistive layer are made from the same polycrystalline silicon material, both of them are planarly adjoined each other thereby to form a conductive/resistive layer and there is no overhanging edges.

The doping method above described uses mainly boron (B), phosphorous (P) and arsenic (As) elements as the dopants, and the doping driven-in procedure can be a high temperature diffusion method or ion implantation method. The high temperature diffusion method includes the step of diffusing the gases containing boron, phosphorous and arsenic elements into the surface of polycrystalline silicon layer at a temperature ranging from about 800° C. to about 900° C. The ion implantation method includes the step of implanting the ions containing the boron, phosphorous and arsenic ion into the polycrystalline silicon layer by the ion implanter in order to change the resistivity of the polycrystalline silicon layer. In the present invention, depending on the needs for the resistivity and conductivity, the doping step can be carried out only on the conductive layer, or otherwise, on both the resistive layer and resistive layer by different extent of doping ratio or doping time.

A passivation layer is formed on the conductive layer/resistive layer of the polycrystalline silicon layer by CVD or a sputtering technique. A preferred embodiment of the passivation layer may be a layer of silicon nitride (Si₃N₄) or silicon carbide (SiC) or tantalum (Ta).

By applying the VIA Hole technique, the VIA is defined on the passivation layer using a photolithography and etching method. The adhesion layer and second conductive layer are formed on the passivation layer by sputtering or other known methods per se. The adhesion layer may be a tantalum (Ta) layer and the second conductive layer may be a gold (Au) layer. Finally, all the procedures are completed by defining the desired dimension of the adhesion layer and second conductive layer by using a photolithography and etching method.

### BRIEF DESCRIPTION OF THE DRAWINGS

FIG. 1 is a schematic diagram showing a conventional manufacturing process of the ink jet printhead chip;

FIG. 2 is a schematic structure diagram showing the structure of the conventional of the ink jet printhead chip;

FIG. 3 is a top view of the thin film type ink jet printhead chip as described in U.S. Pat. No. 4,809,428;

FIG. 4 is a cross sectional view taken along on line 4A-4A of FIG. 3;

FIG. 5 is a cross sectional view of the printhead chip structure according to the present invention;

FIG. 6 is a top view of the printhead chip structure according to the present invention;

FIG. 7-1 is a schematic diagram showing the preferred manufacturing procedure 1 of the printhead chip according to the present invention;

FIG. 7-2 is a schematic diagram showing the preferred manufacturing procedure 2 of the printhead chip according to the present invention;

FIG. 7-3 is a schematic diagram showing the preferred manufacturing procedure 3 of the printhead chip according to the present invention;

FIG. 7-4 is a schematic diagram showing the preferred manufacturing procedure 4 of the printhead chip according to the present invention;

FIG. 7-5 is a schematic diagram showing the preferred manufacturing procedure 5 of the printhead chip according to the present invention;

FIG. 7-6 is a schematic diagram showing the preferred manufacturing procedure 6 of the printhead chip according to the present invention;

FIG. 7-7 is a schematic diagram showing the preferred manufacturing procedure 7 of the printhead chip according to the present invention; and

FIG. 7-8 is a schematic diagram showing the preferred manufacturing procedure 8 of the printhead chip according to the present invention.

### DETAIL DESCRIPTION OF THE PREFERRED EMBODIMENTS

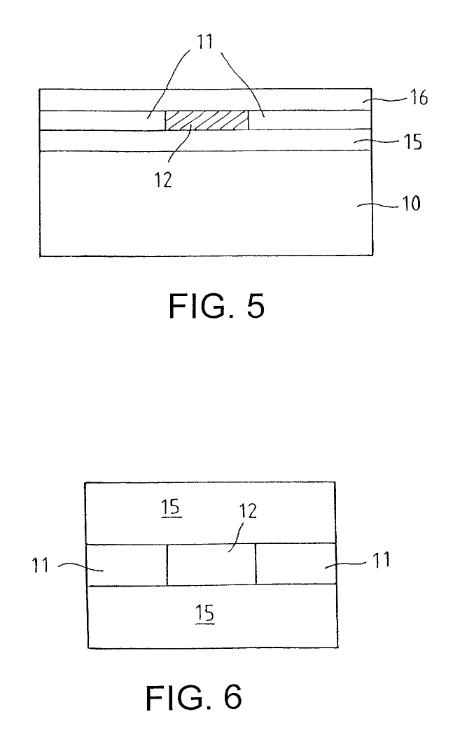

Now referring to FIG. 5 and FIG. 6, it can be seen that, after the printhead chip structure of the present invention is finished, the resistive layer 12 and the conductive layer 11 are located on the same plane and have the same thickness of layer. Therefore, there is no step formed at the interface of the resistive layer 12 and conductive layer 11 and the passivation layer formed on it can be spread uniformly and planarly in order to ensure the planarization of heater plates.

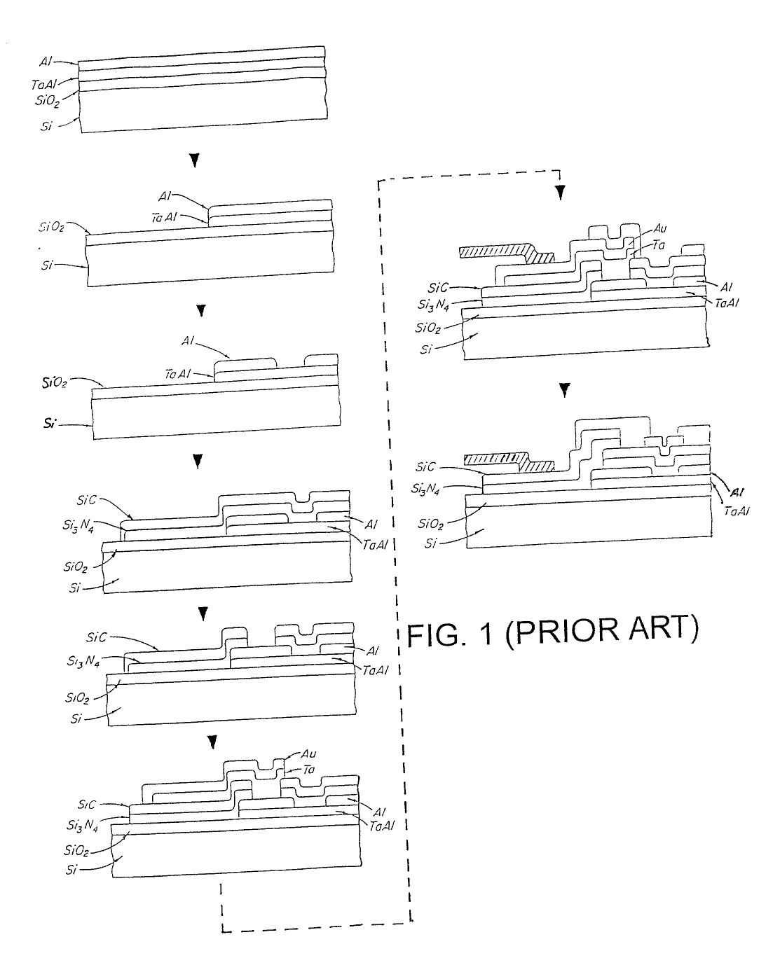

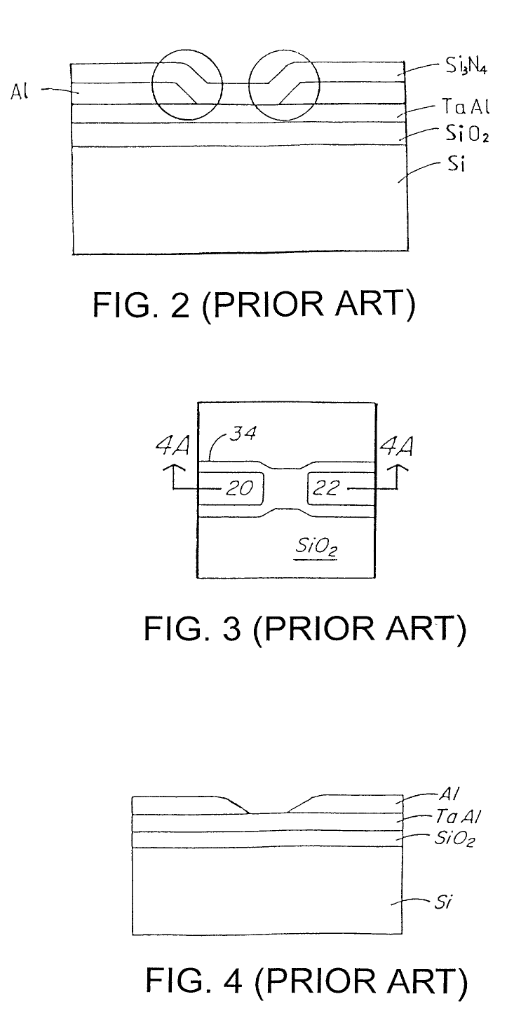

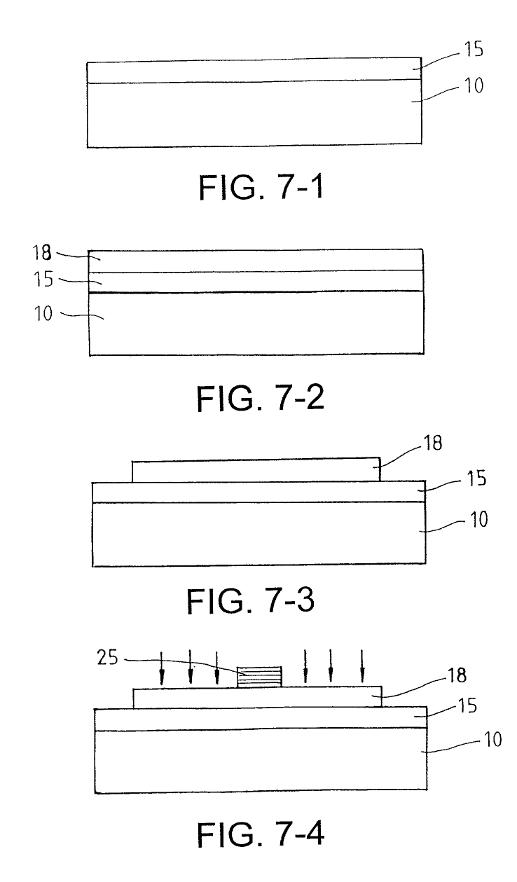

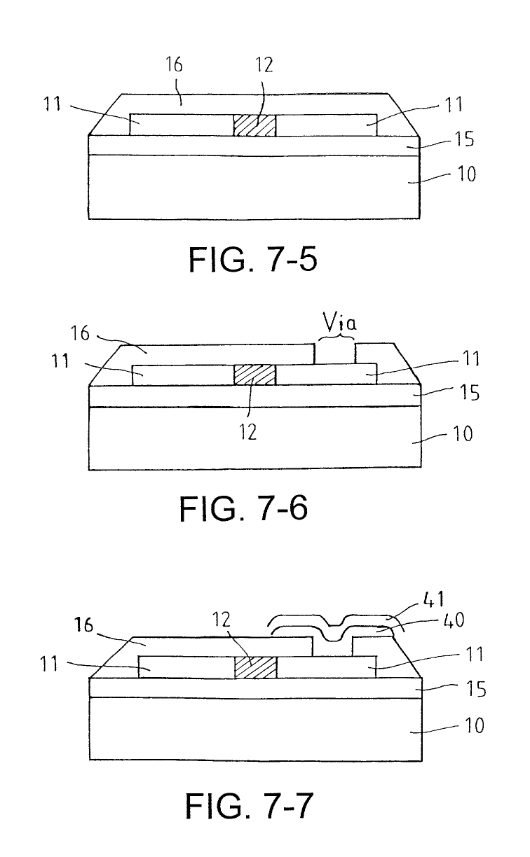

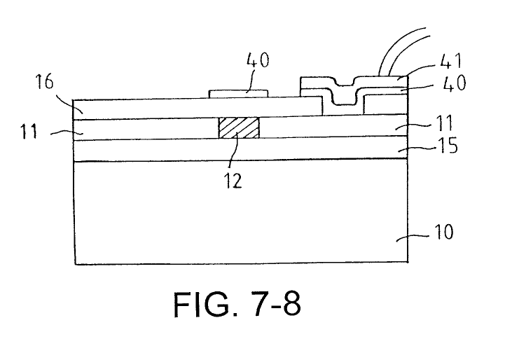

To accomplish the above printhead chip structure, the manufacturing procedures according to the present invention are shown in FIG. 7-1 to FIG. 7-7. Procedure 1 comprises the step of forming a thermal barrier film layer 15 (SiO₂) over the silicon substrate 10 by high temperature diffusion and other known methods per se. Procedure 2 comprises the step of forming a polycrystalline silicon layer 18 with resistance over the thermal barrier layer 15 using CVD or other known methods per se. The polycrystalline silicon layer 18 can be used as a conductive material through the doping process to increase the charged carriers and reduce the resistivity. Procedure 3 comprises the step of defining the polycrystalline silicon layer to the desired dimensions by photolithography and etching technique. Procedure 4 comprises the step of masking a resistive region 12 which is predetermined to form a heater plate on the polycrystalline silicon layer 18 by depositing photoresist 25 and dopes the unmasked region of polycrystalline silicon layer 18 by ion implantation, diffusion or other methods in order to enhance its conductivity and can be used as a the first conductive layer 11. Since the conductive layer 11 and the resistive layer 12 are made from the same polycrystalline silicon layers 18, both of them are planarly adjoined each other thereby to form a conductive/resistive layer and there is no step phenomenon exist. Procedure 5 comprises steps of forming a passivation layer 16 over the first conductive layer 11/the resistive layer 12 of the chip; and then, using the conventional VIA Hole technique in the LSI process, defining VIA on the passivation layer 16 by photolithography and etching technique and then forming the adhesion layer (Ta) and the second conductive layer (Au) by sputtering or other known methods per se and finally defining the desired dimensions by photolithography and etching technique to complete all the procedures.

Compared to the conventional process of fabricating a printhead chip, the structure and manufacturing process of the printhead chip according to the present invention are characterized in that the coating layers of the printhead chips are reduced from the four layers to three layers, that is, thermal barrier layer, conductive/resistive layer and passivation layer, thereby eliminating the step phenomenon and making the passivation layer planar. Since the conductive layer and resistive layer are made from the same polycrystalline silicon layer, it becomes a conductive/resistive layer. This is another advantage of the present invention. Accordingly, the manufacturing process of the present invention simplifies the procedure of manufacturing and enhanced the quality and performance of the printhead chip of the present invention.

While the invention has been described by way of the above examples and drawings, it is to be understood that the invention need not to be limited to the disclosed embodiments. On the contrary, various modifications and changes within the spirit and scope of the present invention, such as the polycrystalline silicon is replaced by other similar materials, are all included within the appended claims.

What is calimed is:

1. A structure of printhead chip for an ink jet printer which comprises a thermal barrier layer formed over a substrate and a polycrystalline silicon layer with resistance formed over said thermal barrier layer, wherein said polycrystalline silicon layer has two separate regions, the first region is a resistive layer which is predetermined to form a heater plate and the second region is a conductive layer which is formed by doping polycrystalline silicon layer, said first conductive layer and resistive layer are made from the same polycrystalline silicon layers, both of them are planarly adjoined each other thereby to form a conductive/resistive layer; and a passivation layer which is formed on said conductive/resistive layer of the chip.

2. A process of manufacturing printhead chip for an ink jet printer according to claim 1, wherein said substrate is a silicon substrate.

3. A process of manufacturing printhead chip for an ink jet printer according to claim 1, wherein said thermal barrier layer is a silicon dioxide (SiO₂) layer.

4. A process of manufacturing printhead chip for an ink jet printer according to claim 1, wherein the method of forming the polycrystalline silicon is CVD or other analogue manners.

5. A process of manufacturing printhead chip for an ink jet printer according to claim 1, wherein said polycrystalline silicon layer is replaced by similar materials with resistance.

6. A process of manufacturing printhead chip for an ink jet printer according to claim 1, wherein the doping method is a high temperature diffusion method which comprises a step of diffusing the gases containing boron, phosphorous and arsenic elements into the surface of polycrystalline silicon layer at a temperature ranging from about 800° C. to about 900° C.

7. A process of manufacturing printhead chip for an ink jet printer according to claim 1, wherein the doping method is an ion implantation method which comprises the step of implanting the ions containing boron, phosphorous and arsenic ion into the polycrystalline silicon layer by an ion implanter in order to change the resistivity of the polycrystalline silicon layer.

8. A process of manufacturing printhead chip for an ink jet printer according to claim 1, wherein the doping method is carried out only on said conductive layer to form said resistive layer and conductive layer.

9. A process of manufacturing printhead chip for an ink jet printer according to claim 1, wherein the doping method is carried out on both the resistive layer and resistive layer by different extent of doping ratio or doping time to form said resistive layer and conductive layer.

10. A process of manufacturing printhead chip for an ink jet printer according to claim 1, wherein said passivation layer is a silicon nitride (Si₃N₄) layer.

11. A process of manufacturing printhead chip for an ink jet printer according to claim 1, wherein said passivation layer is a silicon carbide (SiC) layer.

12. A process of manufacturing printhead chip for an ink jet printer according to claim 1, wherein said passivation layer is a tantalum (Ta) layer.

13. A process of manufacturing printhead chip for an ink jet printer according to claim 1, wherein said passivation layer is a mixture layer of silicon nitride (Si₃N₄), silicon carbide (SiC), and tantalum (Ta).

14. A process of manufacturing printhead chip for an ink jet printer according to claim 1, wherein the manner of forming the via hole is by using the photolithography and etching technique.

15. A process of manufacturing printhead chip for an ink jet printer according to claim 1, wherein the manner of forming the adhesion layer and the second conductive layer is a sputtering method or other analogue manners.

16. A process of manufacturing printhead chip for an ink jet printer according to claim 1, wherein said adhesion layer is a tantalum (Ta) layer.

17. A process of manufacturing printhead chip for an ink jet printer according to claim 1, wherein said second conductive layer is a gold (Au) layer.

18. A process of manufacturing printhead chip for an ink jet printer which comprises the steps of:
1) forming a thermal barrier layer over the substrate;
2) forming a polycrystalline silicon layer with resistance over said thermal barrier layer;
3) defining said polycrystalline silicon layer to the desired dimension by a photolithography and etching technique;
4) masking a resistive region which is predetermined to form a heater plate on said polycrystalline silicon layer by depositing photoresist and doping an unmasked region of said polycrystalline silicon layer in order to form a first conductive layer, the first conductive layer and a resistive layer being made from the same polycrystalline silicon layer, both of them being planarly adjoined each other thereby to form a conductive/resistive layer;
5) forming a passivation layer over said conductive/resistive layer.

19. A process of manufacturing printhead chip for an ink jet printer according to claim 18, wherein said step 5) further comprises the steps of:
a) defining a via hole on said passivation layer by a VIA Hole technique using the photolithography and etching technique;
b) forming an adhesion layer and a second conductive layer on said VIA of passivation layer;
c) defining a desired dimension by photolithography and etching technique.

20. A process of manufacturing printhead chip for an ink jet printer according to claim 18, wherein said substrate in step 1) is a silicon substrate.

21. A process of manufacturing printhead chip for an ink jet printer according to claim 18, wherein said thermal barrier layer in step 1) is a silicon dioxide (SiO₂) layer.

22. A process of manufacturing printhead chip for an ink jet printer according to claim 18, wherein, in step 2), the method of forming the polycrystalline silicon is CVD or other analogue manners.

23. A process of manufacturing printhead chip for an ink jet printer according to claim 18, wherein said polycrystalline silicon layer in step 2) is replaced by similar materials with resistance.

24. A process of manufacturing printhead chip for an ink jet printer according to claim 18, wherein, in step 4), the doping method is a high temperature diffusion method which comprises a step of diffusing the gases containing boron, phosphorous and arsenic elements into the surface of polycrystalline silicon layer at a temperature ranging from about 800° C. to about 900° C.

25. A process of manufacturing printhead chip for an ink jet printer according to claim 18, wherein, in step 4), the doping method is an ion implantation method which comprises a step of implanting a plurality of ions containing boron, phosphorous and arsenic ion into the polycrystalline silicon layer by an ion implanter in order to change a resistivity of the polycrystalline silicon layer.

26. A process of manufacturing printhead chip for an ink jet printer according to claim 18, wherein, in step 4), the doping method is carried out only on said conductive layer to form said resistive layer and conductive layer.

27. A process of manufacturing printhead chip for an ink jet printer according to claim 18, wherein, in step 4), the doping method is carried out on both the resistive layer and resistive layer by different extent of doping ratio or doping time to form said resistive layer and conductive layer.

28. A process of manufacturing printhead chip for an ink jet printer according to claim 18, wherein, in step 5), said passivation layer is a silicon nitride (Si₃N₄) layer.

29. A process of manufacturing printhead chip for an ink jet printer according to claim 18, wherein, in step 5), said passivation layer is a silicon carbide (SiC) layer.

30. A process of manufacturing printhead chip for an ink jet printer according to claim 18, wherein, in step 5), said passivation layer is a tantalum (Ta) layer.

31. A process of manufacturing printhead chip for an ink jet printer according to claim 18, wherein, in step 5), said passivation layer is a mixture layer of silicon nitride (Si₃N₄), silicon carbide (SiC), and tantalum (Ta).

32. A process of manufacturing printhead chip for an ink jet printer according to claim 18, wherein, in step c), the manner of forming the adhesion layer and the second conductive layer is a sputtering method or other analogue manners.

33. A process of manufacturing printhead chip for an ink jet printer according to claim 18, wherein, in step c), said adhesion layer is a tantalum (Ta) layer.

34. A process of manufacturing printhead chip for an ink jet printer according to claim 18, wherein, in step c), said second conductive layer is a gold (Au) layer.
